(19) United States
(12) Patent Application Publication
(10) Pub. No.: US 2011/0037346 A1
(43) Pub. Date: Feb. 17, 2011

(54) PIEZOELECTRIC DRIVE SYSTEM, AND METHOD FOR THE OPERATION THEREOF

(76) Inventors: Walter Haussecker, Buehlertal (DE); Vincent Rieger, Karlsruhe (DE); Volker Rischmueller, Leonberg (DE); Dirk Guenther, Jugenheim (DE); Peter Froehlich, Changsha (CN)

Correspondence Address: MERCHANT & GOULD PC, P.O. BOX 2903, MINNEAPOLIS, MN, 55402-0903, US

(21) Appl. No.: 12/599,238

(22) PCT Filed: Apr. 15, 2008
(86) PCT No.: PCT/EP08/54534

§ 371 Date: Oct. 13, 2010

(30) Foreign Application Priority Data
May 7, 2007 (DE) 102007021335.4

(51) Int. Cl. H01L 41/09

(52) U.S. Cl. 310/316.01

(57) ABSTRACT

Disclosed are a method for operating a piezoelectric drive system (10) used for adjusting movable parts (12, 14), especially in a motor vehicle (13), as well as a piezoelectric drive unit (10) comprising at least one piezo motor (12) that is fitted with at least one piezo actuator (18). At least one frictional element (30) of the piezo motor (12) makes it possible to generate a relative movement in relation to a frictional surface (14) located across from the frictional element (30). The at least one piezo actuator (18) is triggered with an excitation signal (93) by means of an electronic unit (42). A response signal (130) of the drive system (10) is detected using the at least one piezo actuator (18), a change in the load of the drive system (10) being recognized as a result of a change in the response signal (130).

### TECHNICAL FIELD

The invention relates to a piezoelectric drive system used for adjusting movable parts, especially in a motor vehicle, according to the class of the independent claim.

A window system is known from the European patent EP 1 091 074 B1, wherein the window is adjusted using a drive means, which comprises a piezo-drive actuator. The piezo-drive actuator has a piezo element, which moves the window along a guide means by way of the piezo effect. The drive means thereby has a measuring transducer, which supplies a measured value for the driving force to the electrical control unit. Said value can also be used for an anti-jamming device. Such a sensor has, however, the disadvantage of working independently of the piezo drive, respectively of its excitation mode, and of requiring additional evaluation time. Furthermore, a sufficient sensibility can not be achieved for certain jamming situations because the sensor is not adapted to the operational mode of the piezo drive.

### SUMMARY

### Detailed Description

The method according to the invention for operating a piezoelectric drive system and the piezoelectric drive system with the characteristics of the independent claims have in comparison the advantage that a response signal of the piezo actuator, which is employed to exert a driving force on the movable part, can be used for detecting a change in the load in the drive system. In so doing, the piezo actuator is triggered with an excitation signal for the adjustment operation, so that the response signal of the piezo actuator is on the one hand dependent on the excitation signal and on the other hand acquires the response of the entire system to the excitation signal. A very fast and accurate change in the load of the movable part is thereby acquired, whereby a very reliable anti jamming function is assured. At the same time, the item of information from the response signal can likewise be evaluated for the closed-loop control of the drive system. The use of an additional detector and its electrical supply is avoided by the double usage of the piezo actuator as a drive and as a sensor so that the number of components is significantly reduced. This reduction in the number of components thus leads to a reduction in the weight.

Advantageous modifications and improvements in the embodiments stated in the independent claims are possible as a result of the measures listed in the dependent claims. In order to adjust the movable part, the piezo actuator is triggered by means of an excitation signal for executing an adjusting movement. If the response signal is now simultaneously detected during this normal excitation operation of the piezo actuator, the item of information about the change in the load of the movable part is present without a time delay. If the response signal is likewise used for the closed-loop control of the adjustment system, no additional components are necessary for the anti-jamming function so that the piezo actuator simultaneously acts as both a driving means and a load sensor.

In a further embodiment of the invention, the normal excitation operation of the piezo actuator is briefly interrupted in order to acquire the response signal of the drive system to the excitation signal of the piezo actuator. This has the advantage of not having to separate the response signal from the excitation signal, whereby an even more sensitive signal can be detected. Because the interruption of the excitation operation lies in the millisecond range, the individual, brief interruptions do not disruptively impact the adjustment operation.

It is particularly advantageous for the load detection to measure the amplitude of the current signal, respectively the change in said amplitude. In so doing, the amplitude of the excitation voltage can advantageously be held constant, for example, at its maximum value. The change in the current amplitude thus represents a benchmark, which can be compared to a limit value in order to recognize an incident of jamming.

The amplitude of the voltage can also alternatively be measured for recognizing the change in the load, the maximum amplitude of the excitation current being preferably held constant.

Because the piezo actuator is preferably operated as the excitation signal at a certain resonance frequency, a change in this excitation frequency as a result of a change in the load in the system can also be detected as the response signal. In so doing, a shift of this excitation frequency of the current signal/voltage signal represents a measurement for the change in the load.

A special test signal can be provided to the piezo actuator for detecting the change in the load, and the response signal of the drive system can thereupon be detected. In so doing, the current amplitude or the voltage amplitude or the change in frequency can, for example, be measured. A step function, a certain peak shape or a ramp progression of the envelopes of the high frequency signal are particularly suited to be a test signal.

In an additional embodiment, the damping action of the piezo actuator due to its decay characteristics is acquired after the normal excitation signal is switched off. This is done in order to detect the load of the part to be adjusted.

During the start-up of the excitation operation, the transient response of the piezo actuator can alternatively be detected in order to acquire the driving force to be applied. In order to achieve a higher sensitivity in the load detection, excitation can occur at another operating point during the normal adjustment operation of the piezo actuator. This operating point can, for example, have an excitation frequency or current amplitude, respectively voltage amplitude, of the excitation signal which deviates from the normal excitation operation in order to achieve a stronger response signal of the adjustment system at this operating point. When using the same piezo actuator, said actuator can thereby on the one hand be optimized to the adjustment operation and on the other hand to the sensor operation.

In order to release the anti jamming function, for example when stopping or reversing the movable part, the response signal, respectively its change versus time or versus the adjustment travel, is continually compared with a limit value. This limit value can be empirically ascertained and/or ascertained via a learning process based on the change in the previous adjustment processes.

In order to evaluate the response signal, a model is advantageously taken as a basis, which represents the piezoelectric drive system. In so doing, the system can be seen as an oscillating system, wherein the change in the response signal is represented by a change in the components of the oscillating system.

Due to the fact that in each case only one piezo actuator of a piezo motor is triggered, the activation electronics of said motor is significantly simplified. The oscillation behavior of the piezo motor is only determined by the one single excitation frequency so that the movement path of the push rod can be simply specified. In the case of outside influences, as, for example, a change in the load, which upset the resonance frequency, the resonance frequency can be much more simply tracked with a single-phase excitation. In addition the non-triggered piezo actuator can simultaneously be used as an anti jamming sensor, respectively load sensor, which converts a mechanical application of a force by the part to be adjusted into an electrical sensor signal. The piezo motor is fitted for, for example, exactly two piezo actuators. These can be favorably operated in such a way that a piezo actuator is triggered in each case for one direction of movement of the relative movement. This has the advantage in that always only exactly one piezo actuator is set into oscillation by means of the electronic unit, and the second piezo actuator merely resonates as an inert mass. In so doing, a complicated overlapping of the two simultaneously triggered piezo actuator oscillations is prevented.

By operating the piezo actuators in their resonance frequency, their piezo ceramics are optimally utilized. A large deflection of the piezo actuator can thereby be generated with a relatively small material usage of the piezo ceramic, whereby a large forward feed, respectively a large torque, can be transferred to the corresponding frictional surface. The piezo ceramic is operated at the point of its maximum efficiency as a result of the resonance operation, whereby the electrical power loss is greatly reduced and a heating-up of the piezo ceramic is consequently avoided. During the resonance operation, the piezo ceramic, the electronic unit and the voltage source are not loaded with idle power, whereby the electronics can be more easily executed; and additional switches and filter elements can be eliminated. By utilizing the dielectricity of the piezo ceramic, no disturbing electromagnetic fields are produced and the operation of the piezo ceramic is not noticeably impaired by external magnetic fields. When operating the piezo actuator in the resonance operation, the amplitude and the power transmission by the piezo actuator onto the corresponding frictional surface can be adapted by way of the design of the piezo actuator. Due to the high power density of the piezo actuator, the material usage of the relatively cost intensive piezo ceramic can be reduced, respectively the power output of the piezo drive can be increased. When compared with conventional electrical motors, there are also no starting currents or blocking currents so that a significantly higher degree of efficiency of the piezo drive can be achieved.

According to one embodiment of the drive unit according to the invention, the piezo actuator is exclusively set into longitudinal oscillations so that only oscillation components in the longitudinal direction with the largest distention of the piezo actuator are activated. The piezo ceramic and the configuration of the housing of the piezo actuator are correspondingly optimized for this purpose. If the longitudinal axis of the piezo actuator is substantially aligned perpendicular to the corresponding frictional surface of the drive element when said actuator is at rest, the longitudinal oscillation of a single piezo actuator can be effectively transferred into the one or into a plurality of opposing direction(s) of motion of the relative movement in relation to the frictional surface.

If the piezo ceramic is configured in a plurality of layers, between which electrons are connected up, a larger oscillation amplitude can be generated with a specified voltage. If the layers are arranged at right angles to the longitudinal axis of the piezo actuator, the longitudinal oscillation is thereby maximized in the longitudinal direction.

Due to the micro jabbing motion of the friction element relative to the corresponding frictional surface, a relative movement can be generated without having to set additional inert masses into motion. By means of a suitable selection of frictional partners between the frictional element and the corresponding frictional surface, the oscillation of the piezo actuator can be converted into a linear motion or a rotational motion of a drive element in a very low-loss and wear-resistant manner. In order to support the power transmission, a positive fit—for example: a micro-gearing—in addition to the frictional fit can be configured between the frictional element and the frictional surface. The drive element with the frictional surface can be advantageously configured as a linear drive rail or as a rotor shaft. The tangential component of movement of the frictional element is transmitted to the drive element by the holding force, with which the frictional element is pressed against the linear rail or the rotational body. It is particularly favorable to fix the piezo motor to the movable part so that said motor with the movable part moves away from a fixed frictional surface. The piezo motor can, for example, be attached to a window pane and can push off along a frictional surface of a guide rail fixed to the body of the motor vehicle.

Examples of embodiment of the invention are depicted in the drawings and explained in detail in the description below. The following are shown:

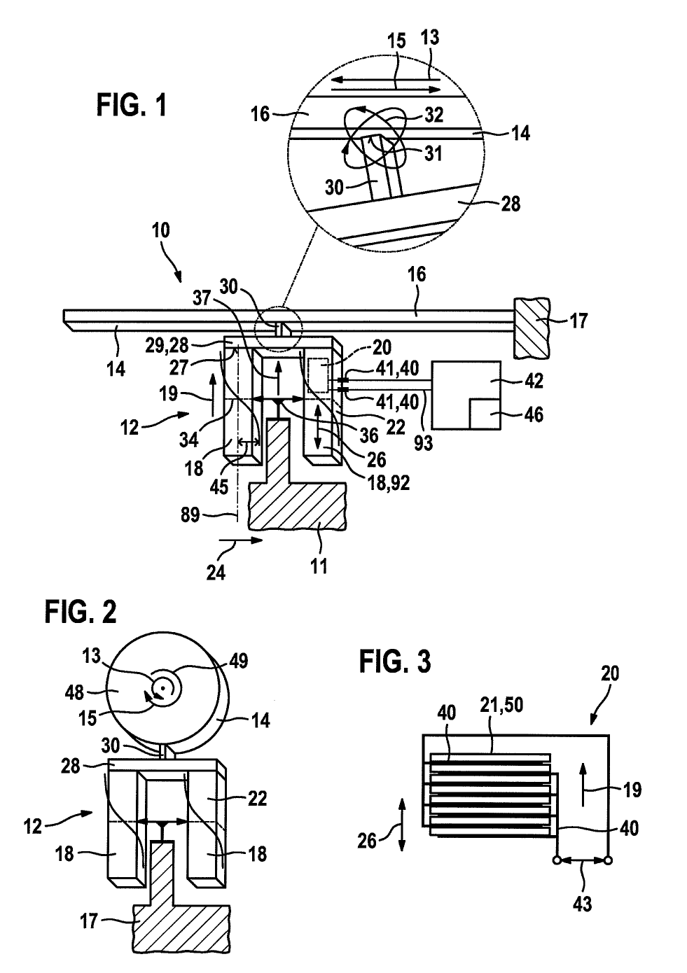

FIG. 1 a piezoelectric drive unit according to the invention,

FIG. 2 a further embodiment for a rotational drive,

FIG. 3 a piezo element for installation into the piezo actuator according to FIG. 1,

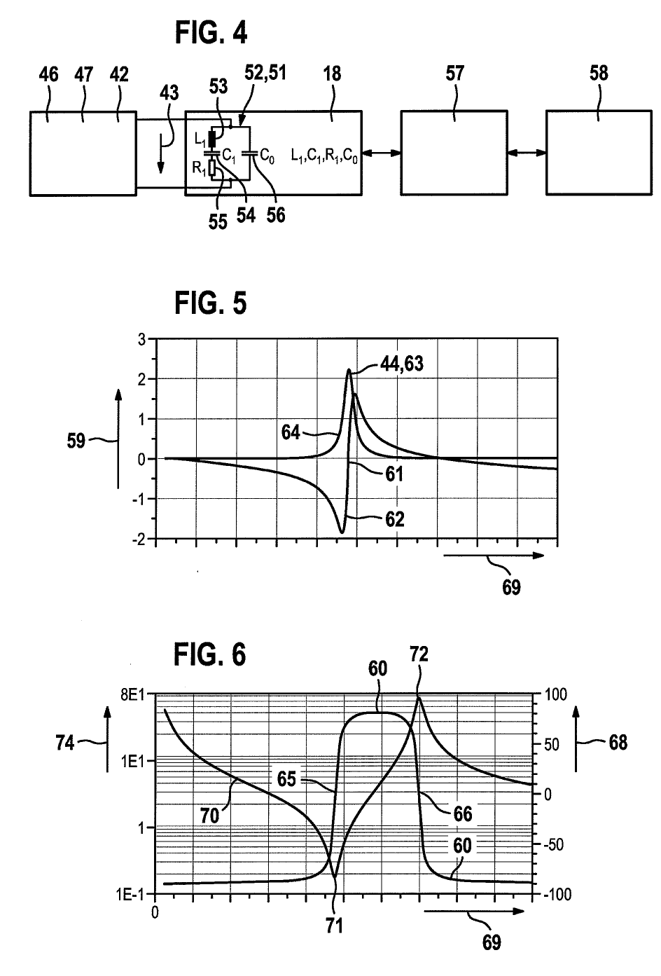

FIG. 4 a schematic depiction for operating the drive unit,

FIG. 5 a resonance curve of the piezo motor and

FIG. 6 an impedance characteristic for the piezoelectric drive system, and

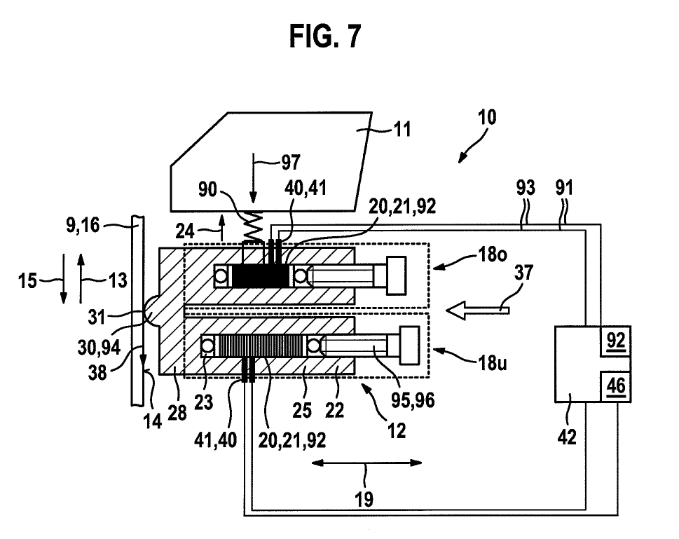

FIG. 7 a further example of embodiment of a drive unit with an integrated load sensor,

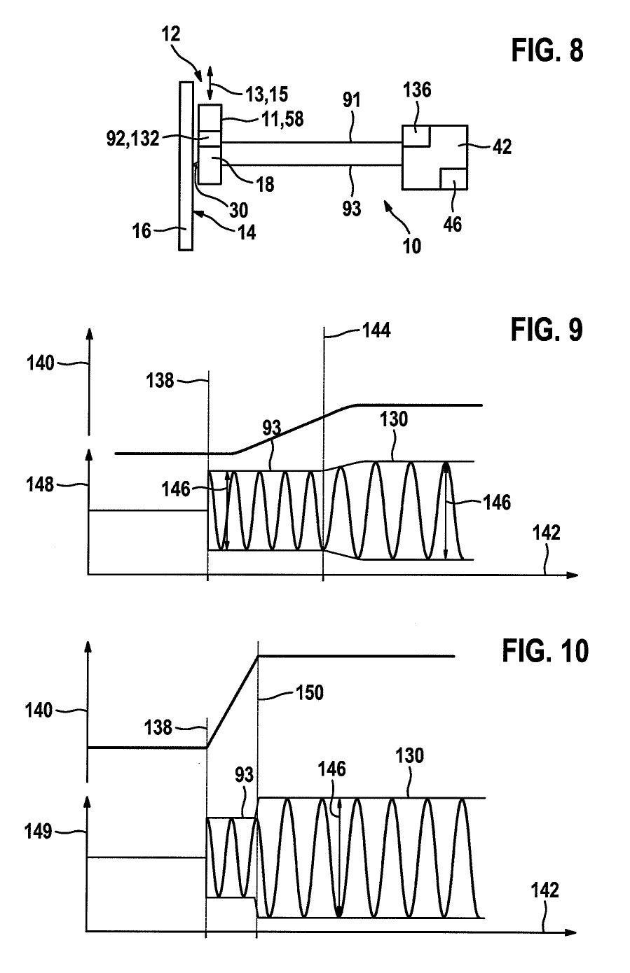

FIG. 8 an embodiment with a separately configured load detector,

FIGS. 9, 10 two depictions of typical progressions of the response signal.

A piezoelectric drive unit 10 is depicted in FIG. 1, wherein a piezo motor 12 executes a relative movement in relation to a corresponding frictional surface 14. The frictional surface 14 is configured in this instance as a linear rail 16, which, for example, is attached to a body part 17 of a motor vehicle. The piezo motor 12 has at least one piezo actuator 18, which in turn contains a piezo element 20. In this connection, the piezo actuator 18 has an actuator housing 22, which accommodates the piezo element 20. The actuator housing 22 is, for example, configured in the shape of a sleeve. The piezo element 20 is enclosed by the actuator housing 22 in the depicted embodiments. The piezo actuator 18 has a longitudinal axis 19, in whose direction the extensions of the piezo actuator 18 are greater than in a lateral direction 24 to said axis. The piezo element 20 is preferably pre-stressed in the longitudinal direction 19 within the actuator housing 22 in such a way that no tensile forces occur in the piezo element 20 when a longitudinal oscillation 26 of said element 20 is activated. The entire piezo actuator 18 is set into longitudinal oscillation 26 by the oscillation of the piezo element 20 and transmits an oscillation amplitude 45 to a frictional element 30, which is in frictional contact with the frictional surface 14, via a bridging web 28. The bridging web 20 is set into a tilting movement or a bending movement by the longitudinal oscillation of the piezo actuator 18 so that an end 31 of the frictional element 30, which faces the frictional surface 14, executes a micro jabbing movement. The interaction between the frictional element 30 and the frictional surface 14 is depicted in the enlarged cut-out, wherein it can be seen that the bridging web 28, which at rest is arranged approximately parallel to the frictional surface 14, tilts in relation to the frictional surface 14 when the piezo actuator 18 is activated into oscillation. In the process, the end 31 of the frictional element 30 executes, for example, an elliptical movement 32, whereby the piezo motor 12 pushes off along the linear rail 16. The piezo motor 12 is mounted in the region of the node 34 of the piezo actuators 18 and is connected, for example, to a part 11 to be moved. At the same time, the piezo motor 12 is pressed with a normal force 37 against the frictional surface 14 via a bearing 36. Thus, the end 31 of the frictional element 30 now executes an elliptical movement 32 or a circular movement, which has in addition to the normal force 37 a tangential force component 38, which brings about the forward feed of the piezo motor 12 in relation to the frictional surface 14. In an alternative embodiment, the frictional element 30 merely executes a linear jabbing movement under a certain angle to the normal force 37. As a result, a relative movement by means of mirco-jabs likewise occurs.

In the example of embodiment according to FIG. 1, the piezo motor 12 is fitted for exactly two piezo actuators, which are both arranged approximately parallel to their longitudinal direction 19. In so doing, the bridging web 28 is laterally arranged to the longitudinal direction 19 and connects the two piezo actuators 18 at their front ends 27. The bridging web 28 is, for example, configured as a level plate 29, in whose middle the frictional element 30 is arranged. In a preferred operational mode of the piezoelectric drive unit 10, only one of the two piezo actuators 18 is activated for a relative movement in the first direction 13. At the same time, the second, non-activated piezo actuator 18 acts via the bridging web 28 as an oscillating mass, on the basis of which the bridging web 28 with the frictional element 30 is tilted or bent in relation to the longitudinal direction 19. The longitudinal oscillation is therefore converted into a micro jabbing movement with a tangential force component 38 corresponding to the torsional rigidity of the construction of the piezo motor 12. The electrical excitation of the piezo element 20 occurs via electrodes 40, which are connected to an electronic unit 42. The piezo element 20 of the other piezo actuator 18 is correspondingly activated by the electronic unit 42 for a movement of the piezo motor 12 in the opposing directions 15. In the case of this operational mode, always only one piezo element 20 of the piezo motor 12 is activated so that an overlapping of two oscillation excitations of the two piezo actuators 18 does not occur.

According to the invention, the piezoelectric drive unit is operated in its resonance frequency 44. The electronic unit 42 has a tuning circuit 46 for that purpose, which triggers the corresponding piezo element 20 in such a way that the entire system oscillates in resonance. In FIG. 1, the amplitudes 45 of the resonance frequency 22 of the longitudinal oscillation 26 are in each case depicted in the two piezo actuators 18, the two piezo actuators 18 not being simultaneously activated in this operational mode. The maximum amplitudes 45 correspond in this instance to the mechanical resonance frequency 44.

In FIG. 2, a variation of the drive unit 10 is depicted, wherein the piezo motor 12 is mounted in a body part 17 of the motor vehicle. The frictional surface 14 is however configured as a peripheral surface of a rotational body 48 so that the rotational body 48 is set in rotation by the ram motion of the frictional element 30. According to the operational mode described in conjunction with FIG. 1, the rotational direction 49 of the rotational body 48 can in turn be specified by the triggering of in each case only one piezo element 20 at one of the two piezo actuators 18. Such a drive unit 10 produces a rotation as a driving motion and can consequently be employed instead of an electrical motor having a gear unit connected downstream.

In FIG. 3, an enlargement of a piezo element 20 is depicted as it can, for example, be used in the piezo motor 12 of FIG. 1 or 2. The piezo element 20 has a plurality of layers which are separated from each other, between which the respective electrodes 40 are arranged. If a voltage is applied at the electrodes 40 via the electronic unit 42, the piezo element 20 expands in the longitudinal direction 19. The expansion, respectively contraction, of the individual layers 50 cumulatively adds up so that the collective mechanical amplitude 45 of the piezo element 20 can be specified in the longitudinal direction 19 using the number of layers 50. The layers 20 are thereby laterally arranged in relation to the longitudinal direction 19 in the actuator housing 22 so that the entire piezo actuator 18 is set into longitudinal oscillation 26 by the piezo element 20. The piezo element 20 is preferably manufactured in such a way that very large amplitudes 45 can be generated in the resonance operation of the piezo element 20.

In FIG. 4, a model of the piezoelectric drive unit 10 is depicted. Said model serves as the basis for the adjustment of the resonance frequency 44 and for the evaluation of the response signal 130 for the load detection. The piezo actuator 18 is thereby depicted as an oscillating circuit 52, wherein an inductance 53 is connected in series with a first capacitance 54 and an ohmic load 55. A second capacitance 56 is connected in parallel thereto. An excitation voltage 43 is applied to this oscillating circuit 52 by the electronic unit 42. The resonance frequency 44 of the piezo actuator 18 is influenced by the conversion of the longitudinal oscillation 26 of the piezo actuator 18 into the ram motion of the frictional element 30. Moreover, the resonance frequency 44 of the entire drive unit 10 depends on the load 58, which is, for example, determined by the weight of the part 11 to be adjusted. The resonance frequency 44 is furthermore dependent on the coupling of the power transmission 57, which is significantly determined by the frictional condition between the frictional element 30 and the frictional surface 14. The equivalent circuit diagram in FIG. 4 simultaneously depicts as a first approximation the electrical clamping behavior of the dynamic piezoelectric drive 10, wherein said drive 10, for example, is operated in the range of the resonance frequency 44. The positive feedback of the change in the load of the part 11 to be adjusted is thereby dependent on the type of power transmission 57 so that the response signal 130 to the excitation signal 93 is dependent on the type of mechanical coupling between the piezo actuator 18 and the part 11 to be adjusted. At the same time, the electrical clamping behavior can also be used according to the equivalent networks 51 for the evaluation of the response signal 130 by the anti jamming module 136.

According to this equivalent circuit, a frequency response, as it is depicted in FIG. 5, arises when the adjustment unit 10 is activated by the electronic unit 42. At this juncture, the power output 59 is plotted versus the frequency 69. A maximum 63 of the real power 64 occurs at the zero crossing 61 of the depicted idle power 62. The maximum 63 of the real power 64 occurs at the resonance frequency 44, to which the piezoelectric drive unit 10 is adjusted by means of the tuning circuit 46. The resonance frequency 44 lies, for example, in the range between 30 and 80 kHz, preferably between 30 and 50 kHz.

In FIG. 6, the associated impedance behavior of the piezo motor 12 is plotted versus the frequency response. The phase profile 60 of the impedance of the adjustment unit 10, which is depicted by the oscillating circuit 52 according to FIG. 4, has a first zero crossing 65 with a positive slope and a second zero crossing 66 with a negative slope, which correspond to the series resonance and the parallel resonance of the oscillating circuit 52. The phase angle 68 is depicted on the y-axis on the right side of the diagram. In order to keep the drive unit 10 in the resonance operation—for example also in the case of a variable load 58—the tuning circuit 46 adjusts the frequency 69, for example, to the zero crossing with a positive slope, which can be implemented relatively simply by means of a phase locked loop 47 (PLL: phase locked loop). The left y-axis depicts the absolute value 70 of the impedance, the impedance plot 70 versus the frequency 69 having a minimum 71 at the first zero crossing 65 and a maximum 72 at the second zero crossing 66.

In FIG. 7, a further example of a piezoelectric drive unit 10 is depicted, wherein the linear rail 16 is configured as the vertical guide 9. The piezo motor 12 likewise has two piezo actuators 18 as in FIGS. 1 and 2, which are arranged in the longitudinal direction 19. The two piezo actuators 18 are connected to each other via a bridging web 28, which, for example, is configured as one piece with the two actuator housings 22. A frictional element 30, whose end 31 is in frictional connection with the frictional surface 14 of the linear rail 16, is in turn configured on the bridging element 28. The frictional element 30 is configured here, for example, as a convex push rod 94, which executes a micro jabbing movement in relation to the rail 16. A piezo ceramic 21, which has a larger distention in the longitudinal direction 19 than in the lateral direction 24, is in each case arranged as a piezo element 20 in the interior of the two actuator housings 22. The piezo elements 20 are mechanically pre-stressed in the longitudinal direction 19. They are as a result clamped within a cavity 23 using clamping elements 95. The clamping elements 95 are, for example, configured as screws 96, which can be directly screwed into threads in the actuator housing 22. The drive unit 10 is configured here as a power window lift drive, whereat the piezo motor 12 with the part 11 to be adjusted is connected. Said part 11 is configured in this case as a window pane. In order to execute a relative movement in a first direction of movement 13 (lift), only the lower piezo actuator 18u is activated by means of the electronic unit 42 according to this embodiment. By activating the lower piezo element 20, the frictional element 30 executes a jabbing movement or an elliptical movement 32, respectively circular movement, whereby the piezo motor 12 pushes off along the first direction of movement 13 using a tangential force component 38. On the basis of mechanical hysteresis of the bridging web 28 arranged at the piezo actuator, the activated longitudinal oscillation 26 is converted into an elliptical movement of the push rod 94, which corresponding to system parameters deviates from a true linear movement. While the lower piezo actuator 20 is activated, no excitation signal 93 is applied to the upper piezo actuator 18o. In fact when moving in the direction 13, the part 11 to be adjusted exerts a force 97 in the lateral direction 24 on the piezo element 20 of the upper piezo actuator. The piezo element 20 is thereby mechanically loaded in the lateral direction 24, whereby a sensor signal 91 can be tapped at the electrodes 40. The sensor signal 91 is evaluated in the electronic unit 42, and the piezoelectric drive 10 can then be stopped or reversed when a specifiable threshold is exceeded. Only the upper piezo actuator 18o is then activated to lower the part 11 to be adjusted along the second direction of movement 15 without an excitation signal being applied to the lower piezo actuator 18u. In this manner, only one piezo actuator 18u, 18o is triggered in each case for each direction of movement 13, 15. Hence there is no overlapping of a plurality of excitation signals 93, whereby the piezo motor 12 is always triggered in only one phase.

In so doing, the identical excitation signal 93, which is generated by the tuning circuit 46 of the electronic unit 42, can be used for the excitation of the lower piezo actuator 18u and for the excitation of the upper piezo actuator 18o. When lowering the movable part 11, the lower piezo actuator 18u can likewise selectively be operated as a sensor 92. There is however no necessity for this action in the case of a power window lift drive because no danger of jamming exists during said lowering. Therefore, either the lower piezo actuator 18u for lifting the part 11 or the upper piezo actuator 18o for lowering the part 11 can be successively triggered with a single electronic unit 42 having a single tuning circuit 46. The mounting of the piezo motor 12 is not depicted in detail in FIG. 7 but can, for example, be carried out in a manner similar to that in FIG. 1. In so doing, the piezo motor 12 is pressed in the longitudinal direction 19 with a normal force 37 against the frictional surface 14. The movable part 11 is connected to the upper piezo actuator 18o with a connecting element 90, the connecting element 90 preferably being arranged directly in the region of the piezo element 20. In the example of embodiment, the connecting element 90 is elastically configured, for example as a spring element, the spring rate being specifiable for anti jamming reasons by its stiffness. Adjustments can thereby be made as to how soft obstacles can still be detected (for example: finger or neck). In the example of embodiment, the upper piezo element 20 is configured with a smaller volume than the lower piezo element 20 because smaller driving forces are required for the lowering of the part 11 than for the lifting of said part 11 with the lower piezo element 20 which has a longer construction. In a further variation of the invention, the piezo element 20 can also be mechanically loaded in the same direction in order to generate a sensor signal 91, just as the piezo element 20 is also activated for driving the part 11. For example, the part 11 could be connected to the upper piezo actuator 18o using a connecting element 90 in such a way that the upper piezo element 20 is mechanically loaded in the longitudinal direction 19 in order, for example, to generate a sensor voltage.

An alternative embodiment is depicted in FIG. 8, wherein the sensor 92 is designed as a separately configured load detector 132. In so doing, the load detector 132 is additionally disposed next to the piezo actuator 18 at the piezoelectric drive system 10, preferably between the adjusted part 11 and the piezo actuator 18. The load detector 132 is configured, for example, as a path sensor, speed sensor or acceleration sensor, whose sensor signal 91 is evaluated in order to ascertain the load of the part 11 to be adjusted, respectively the adjusting force. The load detector 132 can alternatively be configured as a force sensor 134, which supplies a signal representing the driving force as a sensor signal 91 to the electronic unit 42. The electronic unit 42 has an anti-jamming module 136 for this purpose, wherein the sensor signal 91 or a variable derived from it is compared with a limit value. The limit value is, for example, deposited in a storage unit of the anti jamming module 136, for example, as a constant value or as a limit value-curve plotted versus time, respectively versus the adjustment travel. If the limit value for the jamming protection is exceeded, the electronic unit 42 gives a corresponding signal to the piezo actuator 18, which stops or reverses the adjustment process of the part 11.

The log of a change in the load is schematically depicted in FIG. 9. The upper curve shows the adjustment travel 140 on the y-axis versus the time axis 142 (x-axis). If the load resulting from the part 11 to be adjusted gradually increases and continuously passes into an idleness in a region 144, for example when a power window pane comes up against a stop with a weather strip, the response signal 130 increases only slowly in this region, and then reaches a region of saturation with a larger constant amplitude. In FIG. 9, the current 148, which is plotted on the y-axis versus the time 142 (x-axis), is depicted, for example, as the response signal 130. At the beginning of the adjustment process at the point in time 138, the current signal 148 in the case of an even adjustment of the movable part 11 has a constant, maximum current amplitude 146, with which the piezo actuator 18 is supplied. The frequency of the excitement signal 93 thereby lies, for example, in the range of the resonance frequency 44 and also does not change when a change in the maximum amplitude occurs. Based on the slow, gradual change in the maximum amplitude 146 versus the time 142 in the region 144, the anti jamming module 136 can recognize that a case of jamming is not present, but, for example, an increase in load due to an increase in the friction of the movable part 11 in its guide rail exists.

On the other hand, a case of blocking is depicted in FIG. 10, wherein the anti jamming function is released. After a constant, even adjustment process after the starting point in time 138, a sudden blocking of the part 11 to be adjusted occurs at the point in time 150, which, for example, leads to a stepwise increase in the maximum amplitude 146 of the response signal 130. The excitation voltage 149, which at the point in time of the blocking 150 experiences a very rapid change in the maximum amplitude 146, is depicted in FIG. 10 as the response signal 130 on the y-axis. If, for example, the temporal change in the maximum amplitude 146 of the response signal 130 is compared with a stored limit value, a case of jamming can be recognized when the slew rate of the response signal 130 is exceeded. The piezo motor 12 can thereupon be stopped or reversed.

In a further unspecified embodiment, the frequency of the current 148 and that of the voltage 149 can be measured as the response signal 130, whereby a change in the load by the part 11 to be adjusted can likewise be detected. In the case of blocking, a frequency dependent component, for example: the inductance 53, the first capacitance 54 or the second capacitance 56, can thereby change in the equivalent circuit diagram of the piezo drive 10, whereby the resonance frequency 44 of the adjustment system 10 shifts when a change in the load occurs. If, for example, only the ohmic resistance 55 changes as a result of the change in the load, the resonance frequency 44 remains constant as in FIG. 8, and merely the amplitude 146 of the response signal 130 changes, which corresponds to a change in impedance according to FIG. 6.

It should be noted that with regard to the examples of embodiment shown in the figures and those used in the description, multiple combination possibilities of the individual characteristics among themselves are possible. In so doing, the concrete configuration of the piezo actuators 18, 8 and their actuator housing 22, of the piezo elements 20 (monoblock design, stack or multilayer design), of the bridging web 28 and of the frictional element 30 can be varied according to use. In so doing, the ram motion can be configured as a linear jabbing movement or as a substantially elliptical or circular path of movement. The true linear ram motion thereby depicts the limit case of the elliptical movement. In the case of there being more than 2 piezo actuators 18, the corresponding oscillations of a plurality of piezo actuators of a piezo motor 12 can likewise be simultaneously activated, whereby an overlapping of these oscillations causes a ram motion, which sets the drive element into motion. The piezo actuators 18 can thereby have a single-phase or multi-phase operation. The method according to the invention for recognizing the change in the load is not limited to the micro jab principle, but can be transferred to quasi-statically operating drives, as, for example, the inch worm piezo motor. The drive unit 10 according to the invention is preferably used for adjusting movable parts 11 (seat components, windows, roof, flaps) in the motor vehicle. In so doing, the piezo motor 12 can be operated with the vehicle electrical system voltage. Said unit 10 is however not limited to this particular use. The piezo motor 12 can therefore also be attached to the body of the vehicle, and the frictional surface 14 can be moved with the part 11 to be adjusted, for example with an automatic safety belt feeder or with a head rest.

1. Method for operating a piezoelectric drive system used for adjusting movable parts, especially in a motor vehicle, comprising at least one piezo motor that is fitted with at least one piezo actuator, wherein at least one frictional element of the piezo motor makes it possible to generate a relative movement in relation to a frictional surface located across from the frictional element wherein the at least one piezo actuator is triggered with an excitation signal by means of an electronic unit; and a response signal of the drive system is detected using the at least one piezo actuator, a change in the load of the drive system being recognized as a result of a change in the response signal.

2. Method according to claim 1, wherein the response signal is measured using the activated piezo actuator during a normal excitation operation of the at least one piezo actuator used for adjusting the part.

3. Method according to claim 1, wherein response signal is measured using the activated piezo actuator after interrupting the normal excitation operation of the piezo actuator used for adjusting the part.

4. Method according to claim 1, wherein a current amplitude—especially when the excitation voltage is held constant—is measured as the response signal of the system.

5. Method according to claim 1, wherein a voltage amplitude—especially when the excitation current is held constant—is measured as the response signal of the system.

6. Method according to claim 1, wherein a shift of the resonance frequency of the drive system is measured as the response signal of the system.

7. Method according to claim 1, wherein a test signal is supplied to the piezo actuator as the excitation signal; and the response signal of the system to the test signal is measured, the test signal being configured in particular as a step function, a peak or a ramp.

8. Method according to claim 1, wherein the decay characteristics of the previously activated piezo actuator are measured as the response signal after interrupting the normal excitation operation of the piezo actuator in order to recognize a change in load in the drive system.

9. Method according to claim 1, wherein the transient response of the piezo actuator during the normal excitation operation is evaluated as the response signal in order to recognize a change in the load in the drive system.

10. Method according to claim 1, wherein the piezo actuator is briefly operated at another operating point—deviating from the normal excitation operation—during the normal, closed-loop controlled excitation operation, said operating point being optimized to the influencing variable of the load, wherein especially the excitation frequency and/or the amplitude of the excitation signal is varied in order to recognize a change in load in the drive system.

11. Method according to claim 1, wherein a case of jamming is recognized and the piezo motor is stopped or reversed if the change in the response signal exceeds a specifiable limit value.

12. Method according to claim 1, wherein the piezo actuator is configured in such a way that an equivalent circuit diagram as a model of the piezoelectric drive is applied to an inductance, a capacitance and an ohmic resistance, which are connected to each other in series, for the evaluation of the response signal, an additional capacitance being connected in parallel to said series circuit, and the change in at least one of these components is used to determine the change in the load.

13. Method according to claim 1, wherein the piezo motor is fitted with exactly two piezo actuators, wherein only the one piezo actuator is actuated for a first direction of movement of the relative movement, and only the other piezo actuator is actuated for the opposite direction of movement.

14. Method for operating a piezoelectric drive unit according to claim 1, wherein the piezo motor is operated in the range of its resonance frequency by a tuning circuit adjusting to the zero crossing of the phase profile or to an extreme value of the impedance and/or of the admittance (reciprocal value of the impedance) of the system.

15. Piezoelectric drive unit for executing the method according to claim 1, wherein the piezo actuator has a longitudinal direction, along which the piezo actuator has a longer distention than in a lateral direction thereto, and the piezo actuator is set into longitudinal oscillation—in particular exclusively in said longitudinal direction without lateral components—by means of the electronic unit, the longitudinal direction of the piezo actuator extending in particular approximately perpendicular to the frictional surface.

16. Piezoelectric drive unit according to claim 1, wherein the piezo actuator has a piezo ceramic with a plurality of separate layers, between which electrodes are arranged, the layers preferably extending laterally to the longitudinal direction of the piezo actuator.
